(19) United States
(12) Patent Application Publication
(10) Pub. No.: US 2012/0109716 A1
(43) Pub. Date: May 3, 2012

(54) ANALYZING UTILITY CONSUMPTION

(75) Inventors: Avichai Giat, Haifa (IL); Dan Pelleg, Haifa (IL); Noam Slonim, Jerusalem (IL); Pnina Vortman, Haifa (IL)

(73) Assignee: International Business Machines Corporation

(21) Appl. No.: 12/938,412

(22) Filed: Nov. 3, 2010

(51) Int. Cl. G06F 17/30; G06F 15/18; G06F 19/00; G01R 21/00; G01F 1/00

(52) U.S. Cl. 705/7.35; 702/62; 702/45; 706/12

(57) ABSTRACT

Consumption levels are monitored over a period of time and analyzed. In response to a determination that a monitored consumption level is above a threshold that is defined based on consumption levels of an associated reference group, a notification may be provided. A plurality of notifications may be prioritizing based on a priority index. The plurality of notifications or portions thereof may be provided based on the determined priorities. The priority may take into account parameters such as for example cost of consumption, variance in respect to past consumption levels, variance in respect to the reference group and the like.

### BACKGROUND

The present disclosure relates to analyzing utility consumption in general, and to analyzing utility consumption received via an Automatic Meter Reading (AMR) system, in particular.

A resource provider may supply a resource, such as for example water or electricity, to consumers. The resource provider may track levels of consumption and bill the consumers according to their respective consumption. The billing may be done under a predetermined schedule, such as monthly or bi-monthly. In some cases, billing may be done based on an estimation of the consumption, such as based on past resource consumption in a similar time of year.

A typical AMR system comprises of meters or similar apparatuses that are configured to track consumption levels. A meter of the AMR may be configured to transmit consumption levels within a predetermined range of time, such as minutes, an hour or the like. The consumption levels may be provided in different manners. For example, an amount of resource consumed since last meter reading (e.g., a kilowatt hour (kWh) for electricity). As another example, the consumption level may be provided using a meter reading indicative of a total amount of resource consumed since a predetermined time (e.g., 3265.03 gallons of water). The meter reading may be indicative to an amount of resource consumed since last reading based on a subtraction of the two meter readings.

### BRIEF SUMMARY

One exemplary embodiment of the disclosed subject matter is a computer-implemented method for analyzing a resource consumption dataset, the method comprising: obtaining the resource consumption dataset, wherein the resource consumption dataset is indicative of a consumption level of the resource in a plurality of metering points over a time period; in respect to substantially each metering point: defining a reference group for the metering point based on a past resource consumption dataset, the reference group comprising metering points associated with a consumption profile of the resource; determining a first portion of the resource consumption dataset associated with consumption in the metering point; determining a second portion of the resource consumption dataset associated with consumption in the reference group; comparing the first portion with the second portion to identify whether the metering point monitored an abnormal resource consumption over the time period in the metering point in comparison to that consumed in the reference group; generating one or more indications, each indication is indicative of a metering point associated with consumption level that is outside a threshold range, wherein the threshold range is defined in respect to the consumption level of the reference group; and providing at least a portion of the one or more indications.

Another exemplary embodiment of the disclosed subject matter is a computerized apparatus for analyzing a resource consumption dataset, the computerized apparatus having a processor and a storage device; the computerized apparatus comprising: a consumption dataset obtainer configured to obtain the consumption dataset, wherein the resource consumption dataset is indicative of a consumption level of the resource in a plurality of metering points over a time period; a learning module configured to define, based on a past resource consumption dataset, a reference group comprising a portion of the plurality of metering points in respect to a metering point of the plurality of metering points; a consumption level identifier configured to identify whether the metering point monitored an abnormal resource consumption over the time period in comparison to that consumed in the reference group, wherein the consumption level identifier is operately coupled to: a comparison module configured to compare a first portion of the resource consumption dataset associated with the metering point with a second portion of the resource consumption dataset associated with the reference group; indication generator configured to generate one or more indications, each indication is indicative of metering points associated with consumption level that is outside a threshold range, wherein the threshold range is defined in respect to the consumption level of the reference group; and an indication provider configured to provide the one or more indications.

Yet another exemplary embodiment of the disclosed subject matter is a computer program product for analyzing a resource consumption dataset, the computer program product comprising: a non-transitory computer readable medium; a first program instruction for obtaining the resource consumption dataset, wherein the resource consumption dataset is indicative of a consumption level of the resource in a plurality of metering points over a time period; a second program instruction for defining a reference group for a metering point based on past resource consumption dataset, the reference group comprising metering points associated with a consumption profile of the resource; a third program instruction for determining a first portion of the resource consumption dataset associated with consumption in the metering point; a fourth program instruction for determining a second portion of the resource consumption dataset associated with consumption in the reference group; a fifth program instruction for comparing the first portion with the second portion to identify whether the metering point monitored an abnormal resource consumption over the time period in the metering point in comparison to that consumed in the reference group; a sixth program instruction for generating one or more indications, each indications is indicative of metering point associated with the consumption level that is outside a threshold range, wherein the threshold range is defined in respect to the consumption level of the reference group; a seventh program instruction for providing at least a portion of the one or more indications; and wherein the first, second, third, fourth, fifth, sixth, and seventh program instructions are stored on the non-tangible computer readable medium.

### THE BRIEF DESCRIPTION OF THE SEVERAL VIEWS OF THE DRAWINGS

The present disclosed subject matter will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIG. 1 shows a computerized environment in which the disclosed subject matter is used, in accordance with some exemplary embodiments of the subject matter;

FIG. 2 shows a block diagram of a system, in accordance with some exemplary embodiments of the disclosed subject matter;

FIG. 3 shows a flowchart diagram of a method, in accordance with some exemplary embodiments of the disclosed subject matter.

### DETAILED DESCRIPTION

The disclosed subject matter is described below with reference to flowchart illustrations and/or block diagrams of methods, apparatus (systems) and computer program products according to embodiments of the subject matter. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

One technical problem dealt with by the disclosed subject matter is to automatically analyze resource consumption dataset arriving from a plurality of metering devices. The metering devices may be a part of an AMR system, providing reading in a relatively short time intervals, such as hours or minutes. Another technical problem is to identify metering points in which there is a consumption level above/below a predetermine threshold, such as for example an unusually high or irregular consumption level, a relatively high consumption level, an irregular or low consumption level, a low consumption level and the like. The consumption may be due to an anomalous use, caused due to various reasons such as for example due to leaks in water pipes, due to unintentionally leaving an electric apparatus, such as a water heater, turned on, due to intentional consumption, due to malicious intervention with metering devices or the like. Yet another technical problem is to identify metering points in which resources are being wasted and to stop wasting the resources. Yet another technical problem is to detect malicious intervention with the metering devices, such as intervention that would lower the measured consumption level below an actual consumption level.

One technical solution is to determine a reference group for each metering point based on past resource consumption dataset associated with the metering point and other metering points. The reference group may be determined dynamically. The reference group may be updated dynamically. The reference group may be determined based on similarity between consumption levels of the metering devices over time. Another technical solution is to compare the consumption level of the metering point with a representative consumption level of the reference group, such as for example an average consumption level. In some exemplary embodiments, a matrix representing consumption levels of the reference group over a period of time, where each vector of the matrix is associated with a different time, may be determined. For each vector, a z-score may be computed. The set of z-scores may be utilized to determine whether the current consumption level is anomalous. Yet another technical solution may include determining a tendency curve of the z-scores to indicate a tendency of the consumption level. Parameters of the tendency curve, such as for example a slope and an intercept, may be analyzed to indicate whether there is an anomalous consumption level and whether the consumption level is abnormally high/low. Yet another technical solution is to define a virtual metering point based on at least a pair of metering points. The consumption level of the virtual metering point may be indicative of a consumption level in a shared portion of a multi-tenant house. Yet another technical solution is to indicate a metering point that is identified as consuming an unusually high/low consumption level and provide notification to a client associated with the metering point. In some exemplary embodiments, the notification may be provided to a portion of clients, based on prioritization of the notifications and based on limited resources available to perform the notifications. Yet another technical solution is to notify a maintenance crew, technician or the like, which will inspect and optionally stop any resource wastage, such as for example leakage.

One technical effect of utilizing the disclosed subject matter is to reduce resource wastage, by notifying clients of unusually high resource consumption. Another effect is an increase in revenue which may be achieved due to reduced adverse effect of client's bill shock, increase in utility of human resources of the resource provider, reduce revenue loss to malicious intervention with the metering devices, or the like. Yet another technical effect is to increase effectiveness of providing notifications to clients by prioritizing the notifications and providing the notifications associated with highest priority. Yet another technical effect is to increase utility of the resource by reducing resource unintentional wastage.

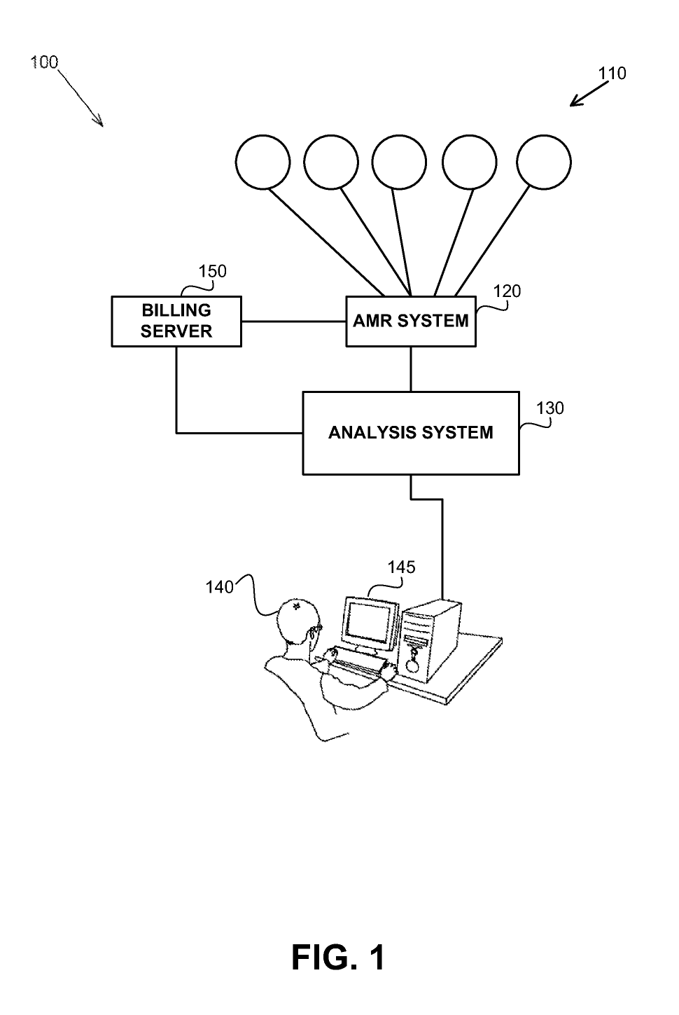

Referring now to FIG. 1 showing a computerized environment in which the disclosed subject matter is used, in accordance with some exemplary embodiments of the subject matter. A computerized environment 100 may comprise an AMR system 120 and an analysis system 130.

The AMR system 120 may comprise a plurality of meters 110. The meters 110 may be configured to detect and provide meter readings of resource consumption levels to the AMR system 120. The meters 110 may provide the readings periodically, such as every hour, every 15 minutes or the like. The meters 110 may be located in different geographic locations. In some exemplary embodiments, one meter of the plurality of meters 110 may be associated with a client, such as a house-hold, a commercial customer, a municipal customer or the like. In some exemplary embodiments, several meters may be associated with the same client. For example, a school campus may be monitored separately for drinking and gardening water using two separate meters. In some exemplary embodiments, several meters may be associated with a common location. For example, a first meter may be associated with a resource consumption within a building, and other meters may be associated with resource consumption within portions of the building, such as apartments. The first meter may be installed on the same resource distribution line as the other meters. A resource distribution line may be, for example, a pipe line, an electric circuit or the like. In some cases, a main resource distribution line may be split into several secondary resource distribution lines (e.g., each associated with a different apartment), each of which is considered as the same resource distribution line in respect to the main resource distribution line. Two meters may be considered on the “same resource distribution line” in case a resource monitored as consumed by the first meter, is also monitored as consumed by the second meter. In other words, in case the resource arrives to the metering point of the first meter, it must have been distributed through the metering point of the second meter. As another example, the first meter may monitor resource consumption within a plurality of buildings, such as located in a campus, whereas the second meter may monitor resource consumption within a portion of the plurality of buildings, such as in a predetermined building (e.g., a sorority house, a faculty, or the like) or a portion thereof.

In some exemplary embodiments, based on the meter readings of the AMR system 120, a billing server 150 may generate a bill for each client. The billing server 150 may issue a bill at predetermined times. The billing server 150 may provide a different cost of consumption for different clients and/or at different times. Other parameters may also affect the cost of consumption.

An analysis system 130 may analyze the meter readings provided by the AMR system 120. The analysis system 130 may provide an indication to a user 140, such as a customer service staff member, a customer relations staff member, a back-office staff member, or the like, of metering points in which a relatively high/low consumption level is/was monitored. In some exemplary embodiments, the indication may be associated with a client (e.g., based on an association between a client and a meter). In some exemplary embodiments, the analysis system 130 may utilize the billing server 150 to determine a cost of consumption, past bills of clients and the like.

In some exemplary embodiments, the analysis system 130 may be configured to detect decrease in consumption over a relatively short period of time, low consumption levels outside the scope or the like. The low consumption level may be caused, for example, due to malicious intervention with the metering devices. For example, a magnet may be utilized to slow down mechanical elements of the metering device, such as a rotor. As another example, may be pouring sugar into a metering device, which may cause ants to crawl into to the metering device and have an adverse effect on the meter's operation. It will be noted that some of the interventions with the meter's operation may reduce the readings by an amount, such as for example 90%, but will not necessarily render a reading of zero consumption. In some exemplary embodiments, similar adverse effects of the metering devices, either intentional, unintentional, malicious or other, may be detected.

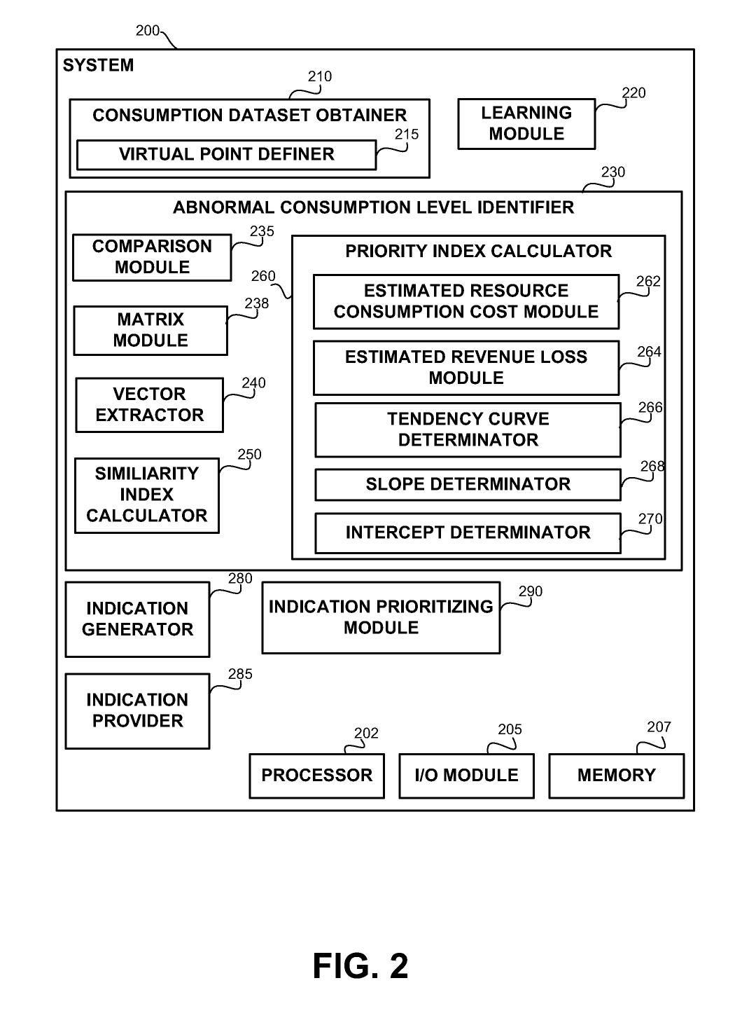

In some exemplary embodiments, the user 140 may utilize a Man Machine Interface (MMI) 145 to review the indications from and/or to provide preferences and input to the analysis system 130. The user 140 may act upon indications, such as by calling, sending a text message, sending an e-mail, initiating an electronic chat session with a client. In some exemplary embodiments, the user 140 may dispatch a service technician, a maintenance crew or the like to inspect the cause of the abnormal consumption level. In some exemplary embodiments, the analysis system 130 may automatically contact the client. In the context of the present subject matter the use of the term abnormal refers to consumption or lack of consumption exceeding predetermined thresholds, or exceeding consumption levels or lack thereof average to the user reviewed, to the reference group of the user reviewed and the like. [0023] Referring now to FIG. 2 showing a block diagram of a system, in accordance with some exemplary embodiments of the disclosed subject matter. A system 200, such as 130 of FIG. 1, may be configured to analyze consumption dataset originating from an AMR system, such as 120 of FIG. 1.

A consumption dataset obtainer 210 may obtain a consumption dataset, such as from the AMR system 120 of FIG. 1. Consumption dataset may be obtained from other sources, such as analysis system 130 of FIG. 1, and from other systems or locations storing or making available such consumption datasets.

In some exemplary embodiments, a virtual point definer 215 may be configured to define a virtual metering point. A virtual metering point may be a source of consumption which is not directly metered by an actual metering device, and which is monitored using readings from several meters. For example, in case of a multi-tenant house, a virtual metering point may be defined to correspond to resource consumption due to a shared segment of the house by subtracting from the consumption level of the multi-tenant house the sum of each tenants' consumption level. It will be noted that a leak in a water pipe associated with a shared segment, such as a shared lawn, may be less likely to be discovered than a leak in a tenant's home. In some exemplary embodiments, a virtual metering point may be defined as a summation of resource consumption levels at a plurality of metering points. In some exemplary embodiments, a virtual metering point may be defined as any computation, such as for example summation and subtraction, of consumption levels associated with a plurality of metering points.

In some exemplary embodiments, a learning module 220 may be configured to define a reference group to a metering point. A reference group comprises metering points that monitor substantially similar consumption levels to that monitored by the metering point. In some exemplary embodiments, the reference group may be determined statically based on static data, such as geographic location, socio-economic characteristics and the like. In some exemplary embodiments, the reference group may be determined dynamically based on the actual consumption monitored in each metering point. In some exemplary embodiments, dynamic determination of the reference group may utilize static information, such as socio-economic characteristics. In some exemplary embodiments, each metering point of the reference group is said to be associated with a consumption profile. For example, the consumption profile may indicate that each metering point consumes about predetermined resource levels at predetermined times. For example, a first consumption profile may indicate a consumption level of about 2 kW electricity during day time and a consumption level of about 8 kW during evenings.

In some exemplary embodiments, the learning module 220 may be configured to receive past resource consumption dataset associated with a relatively long timeframe, such as a month, and based upon the consumption during the timeframe, determine a reference group. The timeframe may be a time immediately preceding the current time (e.g., last month), a corresponding timeframe to a current time (e.g., a corresponding month last year), and the like. The learning module 220 may be configured to compare a vector of consumption readings of the metering point during the timeframe with vectors of other metering points. The comparison may be done by calculating correlation (e.g. Pearson correlation), information metric, Root Mean Square (RMS) and the like. This calculation may be converted to a measure of similarity between metering points. A group of metering points having a relatively high measure of similarity to the metering point may be selected as the reference group. It will be noted that the same metering point may be comprised by several reference groups, each associated with a different metering point. In some exemplary embodiments, the learning module 220 may determine the reference groups based on clusters of metering points. The clusters of metering points may be determined based on clustering techniques.

In some exemplary embodiments, an abnormal consumption level identifier 230 may be configured to identify a relatively high/low consumption level during a time period. For the ease of explanation only, below the abnormal consumption level identifier 230 is referred to identification of high consumption level. The disclosed subject matter is not limited to identifying only abnormally high consumption level.

In some exemplary embodiments, the abnormal consumption level identifier 230 may determine relative high consumption levels by comparing monitored resource consumption levels associated with a metering point with corresponding resource consumption levels of metering points in its reference group.

In some exemplary embodiments, a comparison module 235 may be configured to compare a first portion of the consumption dataset associated with the metering point with a second portion of the consumption dataset associated with the reference group. The first and second portions may comprise monitored consumption levels within the time period that is analyzed.

In some exemplary embodiments, a matrix module 238 may be configured to determine a matrix of values, wherein the matrix comprises of monitored consumption levels by metering points of the reference group in the time period that is analyzed. For example, the rows of the matrix may be associated with a different metering point of the reference group and the columns the matrix may be associated with specific times within the time period.

In some exemplary embodiments, a vector extractor 240 may be configured to extract a vector from the matrix. The vector may represent resource consumption levels of the reference group in a specific time.

In some exemplary embodiments, a similarity index calculator 250 may be configured to determine a similarity index between a resource consumption level of a metering point at a specific time and between resource consumption levels of the metering points of the reference group at the specific time. In some exemplary embodiments, the similarity index may be a standard score, or a z-score, of the consumption level of the metering point in respect to average consumption level of the reference group, normalized by the standard deviation in the set of consumption levels monitored by the reference group. In other words: (x−a)/s, where “x” is the consumption level of the metering point, “a” is the average consumption level in a corresponding time in the reference group and “s” is the standard deviation of the values monitored by the reference group. Other similarity indices may be utilized, such as for example, based on mean consumption by the reference group, a peak consumption, a peak consumption at a certain time window (e.g. 0700-0800), percentile or rank of the consumption in the reference group, an indicator variable for being in the 90 percentile or above, a trend of the metering point as compared to the trend of the reference group, or the like. In some exemplary embodiments, the similarity index calculator 250 may calculate similarity based on a vector extracted from the matrix by the vector extractor 240.

In some exemplary embodiments, a priority index calculator 260 may be configured to compute a priority index of the metering point based on similarity indices. The priority index calculator 260 may utilize similarity indices computed by the similarity index calculator 250 in respect to different times within the time period that is analyzed. In some exemplary embodiments, an average, a mean, or the like of the similarity indices may be computed in order to determine a priority index. In some exemplary embodiments, the priority index may be indicative of a higher/lower consumption level than indicated by the reference group. For example, a priority index of 10 may be deemed to indicate higher consumption level than a priority index of five (5) and of minus twenty (−20).

In some exemplary embodiments, an estimated resource consumption cost module 262, also referred to as consumption cost module, may be configured to calculate an estimated cost of consumption. The consumption cost module 262 may be configured to retrieve or otherwise obtain a charge rate of consumption associated with the metering point. The charge rate may be obtained from a billing server, such as 150 of FIG. 1. The charge rate may be associated with a client that is associated with the metering point. In some exemplary embodiments, the priority index may be indicative of a higher/lower expected cost, and not based solely on consumption level. For example, a first metering point may be associated with a charge rate of one USD per gallon of consumed water and a second metering point may be associated with a charge rate of two USD per gallon. In some cases, the first metering point may be associated with a higher/lower consumption level than that of the second metering point (e.g., ten gallons v. eight gallons), the priority index of the second metering point may be higher/lower (e.g., ten gallons v. sixteen gallons). In some exemplary embodiments, the estimated resource consumption cost module 262 may determine the estimated cost of consumption of the resource consumed by the metering point, such as for example by multiplying the level of consumption and the charge rate. In some exemplary embodiments, a plurality of charge rates may apply for a single metering point. In such an exemplary embodiment, the estimated cost may be computed by taking into account the respective charge rate of each unit of consumed resource.

In some exemplary embodiments, an estimated revenue loss module 264 may be configured to calculate an estimated revenue loss due to “bill shock” by a client. “Bill shock” is a phenomenon in which a client, such as a home-owner, is surprised by a higher bill than he expected to receive. As the billing cycle may be longer than few days (e.g., a month, two months or the like), the bill may be much higher than expected by the client. A “bill shock” event may produce excessive interaction between the consumer and the resource provider (e.g., via a call-center). Such interaction may induce added costs to the resource provider. The estimated revenue loss module 264 may estimate a likelihood of interaction from the client due to “bill shock” based on characteristics of the client, a difference between standard bill of the client or of similar clients and expected bill of the client and the like. In some exemplary embodiments, one or more previous bills of the client may be retrieved, such as for example from a billing server 150 of FIG. 1. The previous bills may be utilized to determine a relative increase in cost of consumption based on a current consumption levels in respect to past consumption levels. In some exemplary embodiments, a revenue loss of the resource provider may be calculated based on expected interaction with the client due to “bill shock”, such as based on answering the client's call, messages or the like. In other exemplary embodiments, a different index that corresponds to the expected interaction with the client may be utilized. The priority index may be calculated based on the computations of the estimated revenue loss module 264.

In some exemplary embodiments, a tendency curve determinator 266 may determine a tendency curve of the similarity indices. A tendency curve may be determined using regression methods, such as determining a linear fit to the values of the similarity indices. In some exemplary embodiments, the tendency curve may be inspected to determine a trend of consumption. For example, a positive slope of the tendency curve may represent that the consumption levels of the metering point are getting further and further away from those of the reference group. The tendency curve determinator 266 may determine a linear or non-linear fit for the similarity indices. In some exemplary embodiments, the tendency curve determinator 266 may determine the linear or non-linear fit for z-scores.

In some exemplary embodiments, a slope determinator 268 may determine a slope of the tendency curve. The slope may be determined by determining one or more derivatives of the tendency curve in one or more locations on the tendency curve. In some exemplary embodiments, the slope may be determined based on algebraic calculations, calculus calculations or the like.

In some exemplary embodiments, an intercept determinator 270 may determine an intercept of the tendency curve. In some exemplary embodiments, the intercept may be determined by assigning to a function representing the tendency curve an x-value of zero and calculating the y-value.

In some exemplary embodiments, the priority index calculator 260 may determine the priority index based on parameters of the tendency curve determined by the tendency curve determinator 266. For example, in case a slope of the tendency curve is above a predetermined number, e.g., above zero, a higher priority index may be determined. The priority index may be determined to be higher as the slope is higher (representing a faster rate of monitoring a higher level of consumption than the pertinent reference group). In some exemplary embodiments, a higher priority index may be assigned in respect to a higher positive slope above a first predetermined slope (e.g., zero, positive number or the like) and in respect to a lower positive slope below a second predetermined slope (e.g., zero, negative number or the like). In some exemplary embodiments, the first and second predetermined slopes may or may not be associated. For example the absolute value of the two predetermined slopes may be the same.

In some exemplary embodiments, in case of a flat tendency curve, such as having a slope of about zero, the intercept of the tendency curve may be determined by the intercept determinator 270. The intercept may represent a steady consumption level above/below that of the reference group. The priority index calculator 260 may calculate a higher priority index in respect to a higher/lower intercept of a flat tendency curve. In some exemplary embodiments, the priority index calculator 260 may determine a higher priority index in respect to a higher positive intercept of a flat tendency curve and a higher priority index in respect to a lower negative intercept of the flat tendency curve. In some exemplary embodiments, the higher priority index may be assigned in respect to a positive intercept above a predetermined threshold such as for example one or two standard deviations or the like. In a similar manner, the lower priority index may be assigned in respect to a negative intercept below a predetermined threshold such as for example minus one or two standard deviations or the like. Other parameters/characteristics of the tendency curve may be inspected and/or determined in order to be taken into account for calculating the priority index.

An indication generator 280 may be configured to generate indications. The indications may be indicative of metering points associated with a relatively high/low consumption level. The indications may be messages, notifications or the like. The indication may include an identification of a metering point to which it refers. Indications may be generated in respect to metering points associated a priority index above a predetermined threshold. In some embodiments of the subject matter, the predetermined threshold may be absolute (e.g., above index of five), relative (e.g., above the 95% of the computed priority indices) or the like.

An indication provider 285 may be configured to provide one or more indications to a device, such as for example a device capable of receiving an email, a text message, a telephone call, a fax message, a post mail or the like. The device may be for example a cellular phone, a post box, an email account or the like. The device may be associated with one or more metering points. In some exemplary embodiments, the indication may be displayed in a terminal, may be sent via a fax machine, may be delivered via a text message, may be sent using an e-mail, may be relayed using a telecommunication system such as a telephone, or the like. In some exemplary embodiments, the indication provider 285 may communicate with a user, such as 140 of FIG. 1. In some exemplary embodiments, the indication provider 285 may communicate with a client by transmitting the indication to the client such as directly to the client or indirectly to the client or the like.

An indication prioritizing module 290 may be configured to prioritize the indications generated by the indication generator 280. The indications may be prioritized based on their priority indexes, such that an indication having a higher priority may be provided by the indication provider 285 before an indication having a lower priority index. In some exemplary embodiments, due to limited resources available (e.g., customer service staff members, time or the like) only a portion of the indications may be reviewed in “real-time”. Therefore, the indication prioritizing module 290 may be configured to prioritize the indications such that the relatively most important indications are reviewed and/or handled. The prioritizing mechanism may be based on a different parameters such as, but not limited to, difference between current consumption level and past consumption levels, different between current consumption level and consumption levels of the reference group, cost of consumption, estimated probability of “bill shock”, estimated resource consumption cost, estimated resource consumption cost in comparison to a typical bill, a parameter of a tendency curve, a type of customer (e.g., home owner, commercial consumer, municipal authority or the like), a type of metering point (e.g., actual metering point or a virtual metering point, or the like), or the like.

The memory 207 may be a Random Access Memory (RAM), a hard disk, a Flash drive, a storage device, or the like. The memory 207 may retain the consumption dataset obtained by the obtainer 210, the reference group of each metering point, the defined virtual metering points, or the like.

In some exemplary embodiments of the disclosed subject matter, the system 200 may comprise an Input/Output (I/O) module 205. The I/O module 205 may be utilized to provide an output to and receive input from a user, such as 140 of FIG. 1.

In some exemplary embodiments, the system 200 may comprise a processor 202. The processor 202 may be a Central Processing Unit (CPU), a microprocessor, an electronic circuit, an Integrated Circuit (IC) or the like. The processor 202 may be utilized to perform computations required by the system 200 or any of it subcomponents.

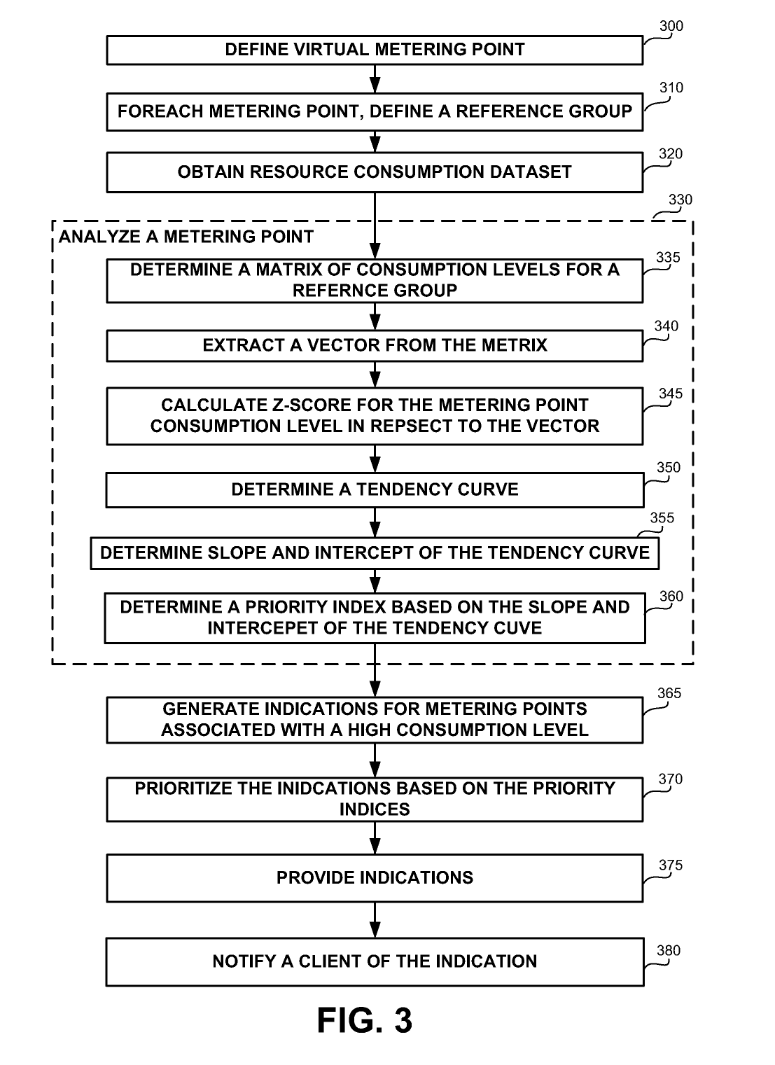

Referring now to FIG. 3 showing a flowchart diagram of a method in accordance with some exemplary embodiments of the disclosed subject matter.

In step 300, a virtual metering point may be defined. The virtual metering point may be defined by a virtual point definer, such as 215 of FIG. 2.

In step 310, a reference group may be defined for one or more metering points. In some exemplary embodiments, a reference group may be defined in respect to each of the metering points or to substantially each of the metering points. The reference group may be defined based on past resource consumption dataset. The reference group may be defined by a learning module, such as 220 of FIG. 2. In some exemplary embodiments, the reference group is determined during a training phase of a system, such as 200 of FIG. 1. The training phase is a phase in which past data is analyzed in order for the system to be familiar with the different behaviors of each metering point. For example, during the training phase data of the past month may be analyzed in order to determine an appropriate reference group for each metering point.

In step 320, a resource consumption dataset may be obtained. The dataset may be obtained by a consumption dataset obtainer, such as 210 of FIG. 2. The dataset may be associated with a timeframe.

In step 330, a metering point may be analyzed based on the dataset obtained in step 320 and based on the consumption levels of the reference group defined in step 310. Step 330 may comprise one or more of the steps 335, 340, 345, 350, 355, 360. Step 330 may be performed several times, each time in respect to a different metering point, virtual or non-virtual, or a combination thereof, or a group of such metering points. For example, step 330 may be performed to analyze each metering point (including the one or more virtual metering points defined in step 300). Step 330 may be performed by an abnormal consumption level identifier, such as 230 of FIG. 2.

In step 335, a matrix of consumption levels for a reference group of the metering point may be determined. The matrix may comprise consumption levels of each metering point of the reference group in different time during the timeframe. For example, in case of a timeframe of thirty hours, the matrix may comprise for each metering point thirty values, a value measured at the beginning of each hour. The matrix may be determined by a matrix module, such as 238 of FIG. 2.

In step 340, a vector may be extracted from the matrix. The vector may comprise a set of values measured in respect to the reference group at a specific time. For example, referring to the example above, the vector may comprise values measured in the beginning of the tenth hour. In some cases, more than one vector may be extracted. The vector may be extracted by a vector extractor 240.

In step 345, a z-score or other similarity index may be calculated for the metering point based on the vector. The similarity index may be calculated by a similarity index calculator, such as 250 of FIG. 2. In some exemplary embodiments, a z-score for the metering point may be computed based on the average consumption level identified in the vector. In some exemplary embodiments, steps 340 and 345 may be performed several times in respect to a plurality of times within the timeframe.

In step 350, a tendency curve of the similarity indices or the z-scores may be determined. The tendency curve may be determined by a tendency curve determinator, such as 266 of FIG. 2.

In step 355, a characteristic of the tendency curve may be determined. In some exemplary embodiments, a slope of the tendency score and/or an intercept of the tendency curve may be determined. The characteristics may be determined by a module such as a slope determinator 268 of FIG. 2, an intercept determinator 270 of FIG. 2, or the like.

In step 360, a priority index may be calculated based on the characteristic of the tendency curve. The priority index may be determined by a priority index calculator, such as 260 of FIG. 2.

In step 365, indications may be generated in respect for metering points associated with priority indices above a predetermined threshold. The indications may be generated by an indication generator, such as 280 of FIG. 2.

In step 370, the indications may be prioritized based on the priority indices. The indications may be prioritized by an indication prioritizing module, such as 290 of FIG. 2.

In step 375, the indications may be provided based on their prioritized order. The indications may be provided by an indication provider, such as 285 of FIG. 2.

In step 380, a client may be notified of an indication concerning a metering point that is associated with the client. The client may be contacted by a user, such as 140 of FIG. 1, automatically by a system, such as 200 of FIG. 2, or the like.

In some exemplary embodiments, a home-owner may be contacted by means of phone call, e-mail, text message or the like, asking the home-owner to have a service technical inspect whether there is a problem. Notifying the home-owner may reduce waste of resources, and reduce likelihood of the home-owner experiencing “bill shock”.

In some exemplary embodiments, a client may be charged for a service of receiving notifications in accordance with the disclosed subject matter. The client may benefit from receiving the notification by reducing wasteful activities in real-time (e.g., employees leaving A/Cs turned on during night). In some exemplary embodiments, the notification system may be configured to meter several resources together, such as, for example both water and electricity.

In some exemplary embodiments, the notification may be provided to service personnel. For example, in a school, use of electricity at night or during the weekend may be notified to a janitor, such as by sending a text message or a page.

In some exemplary embodiments, based on the indication provided in step 375, a resource crew or a similar staff member, may be dispatched to investigate the cause of the relatively high consumption level. The resource crew may be dispatched instead or in addition to notifying the client performed in step 380.

In some exemplary embodiments, step 320-380 may be performed a plurality of times, each time in respect to a different timeframe.

In some exemplary embodiments, the reference group defined in step 310 may be updated. The reference group may be recomputed based on new datasets that are retrieved during the operation of the method. Therefore, in some exemplary embodiments, the reference groups and the membership in them may be dynamic.

In some exemplary embodiments, there are limited resources available to notify a client or dispatch a crew. Therefore, step 370 may be performed to prioritize the different possible activities. The prioritization may be performed based on factors such as: the total amount of resource wasted per time unit; the total estimated cost of consumption; the total estimated cost of consumption in comparison to the average consumption of the same client; the fact that the metering point is a virtual metering point; or the like.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of program code, which comprises one or more executable instructions for implementing the specified logical function(s). It should also be noted that, in some embodiments implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one skilled in the art, the disclosed subject matter may be embodied as a system, method or computer program product. Accordingly, the disclosed subject matter may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product embodied in any tangible medium of expression having computer-usable program code embodied in the medium.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CDROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, and the like.

Computer program code for carrying out operations of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A computer-implemented method for analyzing a resource consumption dataset, the method comprising:
obtaining the resource consumption dataset, wherein the resource consumption dataset is indicative of a consumption level of the resource in a plurality of metering points over a time period;
in respect to substantially each metering point:
defining a reference group for the metering point based on a past resource consumption dataset, the reference group comprising metering points associated with a consumption profile of the resource;
determining a first portion of the resource consumption dataset associated with consumption in the metering point;
determining a second portion of the resource consumption dataset associated with consumption in the reference group;
comparing the first portion with the second portion to identify whether the metering point monitored an abnormal resource consumption over the time period in the metering point in comparison to that consumed in the reference group;
generating one or more indications, each indication is indicative of a metering point associated with consumption level that is outside a threshold range, wherein the threshold range is defined in respect to the consumption level of the reference group; and
providing at least a portion of the one or more indications.

2. The computer-implemented method of claim 1, wherein said obtaining the resource consumption dataset comprises obtaining the resource consumption dataset over the time period from a plurality of metering devices, wherein substantially each metering device is configured to monitor consumption of the resource in a predetermined metering point of the plurality of metering points.

3. The computer-implemented method of claim 1, wherein said comparing comprises:
determining similarity indices, substantially each similarity index is indicative of a similarity between a resource consumption level of the metering point at a time within the time period and between resource consumption levels of the metering points of the reference group at the time; and
generating a priority index of the metering point based on the similarity indices, the priority index is indicative of a consumption level of the metering point outside the threshold range.

4. The computer-implemented method of claim 3, further comprising:
sorting the one or more indications based on the priority indices determining in said generating; and
wherein said providing is performed based on the priority determined in said prioritizing.

5. The computer-implemented method of claim 3, further comprising:
defining a virtual metering point, wherein a resource consumption level of the virtual metering point is defined as a predetermined computation in respect to a set of metering points in the plurality of metering points; and
adding to the resource consumption dataset consumption levels of the virtual metering point.

6. The computer-implemented method of claim 5, wherein said prioritizing comprising giving precedence to the virtual metering point.

7. The computer-implemented method of claim 5, wherein the set of metering points comprising a first metering point and an at least second metering point, wherein the predetermined computation is a subtraction of consumption levels of the at least second metering point from a consumption level of the first metering point, wherein each resource monitored as consumed by the at least second metering point is also monitored as consumed by the first metering point, wherein the first metering point and the at least second metering point are installed on a same resource distribution line.

8. The computer-implemented method of claim 7 wherein the first metering point is associated with at least one building and the at least second metering point is associated with a portion of the at least one building.

9. The computer-implemented method of claim 3, wherein said generating the priority index comprises:
obtaining a charge rate of consumption associated with the metering point; and
determining an estimated cost of consumption of the resource consumed during the time period based on the charge rate.

10. The computer-implemented method of claim 3, wherein said generating the priority index comprises determining an estimated revenue loss due to bill shock of a client associated with the metering point.

11. The computer-implemented method of claim 3, wherein said generating the priority index comprises:
obtaining at least one previous bill associated with the metering point; and
determining a relative increase in cost of consumption associated with the metering point in respect to the at least one previous bill.

12. The computer-implemented method of claim 3, wherein the similarity index is a z-score computed based on a standard deviation of the resource consumption level of the metering point at the time in respect to the resource consumption levels of the metering points of the reference group at the time.

13. The computer-implemented method of claim 3, wherein said generating a priority index comprises:
determining a tendency curve of the similarity indices; and
based on a parameter of the tendency curve, determining the priority index.

14. The computer-implemented method of claim 13, wherein the parameter of the tendency curve is a slope of the tendency curve; and wherein the priority index is indicative of whether an absolute value of the slope is larger than a predetermined slope.

15. The computer-implemented method of claim 14, wherein in response to determining that the slope of the tendency curve is about zero, calculating an intercept of the tendency curve; and wherein the priority index is indicative of whether an absolute value of the intercept is larger than a predetermined intercept.

16. The computer-implemented method of claim 3, further comprises providing a notification to a device associated with a metering point based on the priority index.

17. The computer-implemented method of claim 3, wherein said determining the first portion, said determining the second portion, and said comparing are performed a plurality of times, each time in respect to a different time period; and the method further comprising in response to said obtaining, updating the reference group.

18. A computerized apparatus for analyzing a resource consumption dataset, the computerized apparatus having a processor and a storage device; the computerized apparatus comprising:
a consumption dataset obtainer configured to obtain the consumption dataset, wherein the resource consumption dataset is indicative of a consumption level of the resource in a plurality of metering points over a time period;
a learning module configured to define, based on a past resource consumption dataset, a reference group comprising a portion of the plurality of metering points in respect to a metering point of the plurality of metering points;
a consumption level identifier configured to identify whether the metering point monitored an abnormal resource consumption over the time period in comparison to that consumed in the reference group, wherein said consumption level identifier is operately coupled to:
a comparison module configured to compare a first portion of the resource consumption dataset associated with the metering point with a second portion of the resource consumption dataset associated with the reference group;
indication generator configured to generate one or more indications, each indication is indicative of metering points associated with consumption level that is outside a threshold range, wherein the threshold range is defined in respect to the consumption level of the reference group; and
an indication provider configured to provide the one or more indications.

19. The computerized apparatus of claim 18, wherein said comparison module is operately coupled to:
a similarity index calculator configured to determine a similarity index between a resource consumption level of the metering point at a time within the time period and between resource consumption levels of the metering points of the reference group at the time;
a priority index calculator configured to generate a priority index of the metering point based on similarity indices determined by said similarity index calculator, the priority index is indicative of a consumption level of the metering point outside the threshold range.

20. The computerized apparatus of claim 19, wherein said consumption dataset obtainer is operative to obtain the consumption dataset from an Automatic Meter Reading system, wherein the Automatic Metering Reading system comprises metering devices, wherein the metering devices are configured to automatically transmit meter readings in predetermined timeframes.

21. The computerized apparatus of claim 19, wherein said consumption dataset obtainer is operately coupled to:
a virtual point definer configured to define a virtual metering point, wherein a resource consumption level of the virtual metering point is defined as a predetermined computation in respect to a set of metering point in the plurality of metering points; and
wherein said consumption dataset obtainer is configured to add to the resource consumption dataset consumption levels of the virtual metering point.

22. The computerized apparatus of claim 21, further comprises:
an indication prioritizing module configured to prioritize the one or more indications based on priority indices generated by said priority index calculator;
wherein said indication prioritizing module is configured to give precedence to the virtual metering point; and
wherein said indication provider is configured to provide the one or more indications based on the priority determined by said indication prioritization module.

23. The computerized apparatus of claim 19, wherein said priority index calculator is operately coupled to a module selected from a group consisting of:
an estimated resource consumption cost module configured to calculate an estimation of a cost of resource consumption; and
an estimated revenue loss module configured to calculate an estimation of a revenue loss due to bill shock.

24. The computerized apparatus of claim 19, wherein said priority index calculator is operately coupled to:
a tendency curve determinator configured to determine a tendency curve of similarity indices determined by said similarity index calculator;
a slope determinator configured to determine a slope of the tendency curve;
an intercept determinator configured to determine an intercept of the tendency curve; and
wherein said priority index calculator is configured to determine the priority index based on the slope of the tendency curve and based on the intercept of the tendency curve.

25. A computer program product for analyzing a resource consumption dataset, the computer program product comprising:
a non-transitory computer readable medium;
a first program instruction for obtaining the resource consumption dataset, wherein the resource consumption dataset is indicative of a consumption level of the resource in a plurality of metering points over a time period;
a second program instruction for defining a reference group for a metering point based on past resource consumption dataset, the reference group comprising metering points associated with a consumption profile of the resource;
a third program instruction for determining a first portion of the resource consumption dataset associated with consumption in the metering point;
a fourth program instruction for determining a second portion of the resource consumption dataset associated with consumption in the reference group;
a fifth program instruction for comparing the first portion with the second portion to identify whether the metering point monitored an abnormal resource consumption over the time period in the metering point in comparison to that consumed in the reference group;
a sixth program instruction for generating one or more indications, each indications is indicative of metering point associated with the consumption level that is outside a threshold range, wherein the threshold range is defined in respect to the consumption level of the reference group;
a seventh program instruction for providing at least a portion of the one or more indications; and
wherein said first, second, third, fourth, fifth, sixth, and seventh program instructions are stored on said non-tangible computer readable medium.
